(19) United States
(12) Patent Application Publication
(10) Pub. No.: US 2026/0260916 A1
(43) Pub. Date: Sep. 3, 2026

(54) DIAGNOSTIC METHOD AND DIAGNOSTIC SYSTEM FOR DIAGNOSING A FUEL CELL

(71) Applicant: AVL List GmbH, Graz (AT)

(72) Inventors: Tanner BRUHN, Graz (GB); Laurent ALLOUCHERY, Hart Bei Graz (GB)

(73) Assignee: AVL List GmbH, Graz (AT)

(21) Appl. No.: 18/994,672

(22) PCT Filed: Aug. 22, 2023
(86) PCT No.: PCT/AT2023/060284

§ 371 Date: Jan. 15, 2025

(30) Foreign Application Priority Data
Aug. 23, 2022 (AT) A 50645/2022

(51) Int. Cl. H01M 8/04992

(52) U.S. Cl. CPC H01M 8/04992

(57) ABSTRACT

The present invention relates to a diagnostic method (100) for diagnosing at least one fuel cell of a fuel cell system, wherein the diagnostic method (100) comprises the following steps:
providing (102) at least two different polarisation models (1) for extracting a diagnostic fuel cell parameter set (3) from a polarisation curve (2) of at least one fuel cell,
recording (104) at least one polarisation curve (2) from at least one measurement of at least one fuel cell,
applying (106) at least two of the previously recorded different polarisation models (1) to the at least one polarisation curve (2) of the at least one fuel cell, and
extracting (108) a diagnostic fuel cell parameter set (3) from the at least one polarisation curve (2) of the at least one fuel cell for each of the applied polarisation models (1).

The present invention relates to a diagnostic method and a diagnostic system for diagnosing at least one fuel cell of a fuel cell system as well as a computer program product associated with the diagnostic method.

The polarisation curve is the result of a measurement that can be used to evaluate various properties of a fuel cell. The polarisation curve is a function of the fuel cell design (catalyst, membrane, etc.), the operating conditions (relative humidity, temperature, pressure, etc.) and the ageing of the fuel cell components. The measurement is carried out on the test bench of the fuel cell of a fuel cell system, usually under constant temperature and defined operating conditions.

In the prior art, a polarisation model is used in order to determine diagnostic parameters of the fuel cell from its associated polarisation curve. Such a polarisation model is applied to the polarisation curve so that the desired diagnostic parameters are extracted from the polarisation model. The extracted diagnostic parameters can be used to draw conclusions regarding the fuel cell, for example regarding its degradation.

A problem with the known diagnostic method is that its result depends on the polarisation model used. It may not be possible to extract all desired diagnostic parameters with the polarisation models used. It is also possible that a polarisation model provides inaccurate diagnostic parameters.

It is the object of the present invention to remedy, at least in part, the problems described above. In particular, it is the object of the present invention to provide an improved diagnostic method for diagnosing a fuel cell which provides the most reliable results possible.

The above object is achieved by a diagnostic method with the features of claim 1, a computer program product with the features of claim 11 and a diagnostic system with the features of claim 12. Further features and details of the invention are disclosed in the dependent claims, the description and the drawings. Naturally, features and details described in connection with the diagnostic method according to the invention also apply in connection with the diagnostic system according to the invention as well as the computer program product according to the invention and vice versa, so that with regard to disclosure mutual reference is or can always be made to the individual aspects of the invention.

According to the invention, a diagnostic method for diagnosing at least one fuel cell of a fuel cell system is provided, wherein the diagnostic method comprises the following steps:
providing at least two different polarisation models for extracting a diagnostic fuel cell parameter set from a polarisation curve of at least one fuel cell,
recording at least one polarisation curve from at least one measurement of at least one fuel cell,
applying at least two of the previously recorded different polarisation models to the at least one polarisation curve of the at least one fuel cell, and
extracting a diagnostic fuel cell parameter set from the at least one polarisation curve of the at least one fuel cell for each of the applied polarisation models.

The diagnostic method of the invention thus uses at least two different polarisation models. As described, these polarisation models are used to extract a diagnostic fuel cell parameter set from the respective polarisation curves of one or more fuel cells. Such diagnostic fuel cell parameter sets can also include polarisation losses as fuel cell parameters. These can for example include losses due to membrane permeability, activation losses due to the slow cathode reaction (reaction kinetics), losses due to ohmic resistance (electrical resistance of the electrolyte, catalyst layer, gas diffusion layer, bipolar plates, interface contacts and terminal connections) and concentration losses (delivery of products to the reaction sites, limited by the fluid dynamics at the macro and micro level (convection and diffusion)). Such polarisation models can for example be expressed by one or more mathematical relationships, in particular functions. For example, a polarisation model can be expressed by a function of cell voltage depending on various input parameters, whereby the input parameters can for example be operating parameters, operating conditions, etc. Examples of possible polarisation models are, for example, those of Chamberline-Kim and Larminie-Dicks.

By applying different polarisation models to one or more polarisation curves of one or more fuel cells, not only is a diagnostic fuel cell parameter set extracted and thus obtained, but diagnostic fuel cell parameter sets are obtained for each of the applied polarisation models. In the present case, these diagnostic fuel cell parameter sets represent the diagnosis of the at least one fuel cell because, with the fuel cell parameters contained therein, they represent characteristic data that indicate a condition or status of the fuel cell, for example with regard to degradation. However, this can also be followed by further diagnostic steps, for example an estimate of degradation. Since, according to the invention, at least two diagnostic fuel cell parameter sets for different polarisation models are now available, better diagnostic results are available, because the results are not dependent on a single polarisation model, which may otherwise only make an inaccurate diagnosis. In particular, more accurate diagnostic results can be achieved by comparing the diagnostic fuel cell parameter sets with each other, as will be described in more detail later.

In principle, the diagnostic method can be used to diagnose one or more fuel cells, in particular one or more whole fuel cell stacks, in particular interconnected with each other, or entire fuel cell systems. One polarisation curve can be recorded per fuel cell or per fuel cell stack or per fuel cell system.

The measurement from which the polarisation curve is recorded can in particular be carried out on a test bench of the at least one fuel cell of the fuel cell system, preferably under constant temperature and defined operating conditions. The measurement results of the measurement can already be available when the diagnostic method is carried out, so that only the polarisation curve needs to be recorded from these. However, the measurement can also be carried out as part of the diagnostic method, as will be explained in more detail later.

It is not necessary to carry out all the steps of the method according to the invention in the order in which they are listed. Instead, individual method steps can also be carried out in a different order than this, or simultaneously. In particular, individual or all method steps can also be repeated, in particular being carried out continuously. In this way, the diagnostic fuel cell parameter sets can be extracted and, in particular, also output continuously. This allows live monitoring of the diagnostic method, especially in the case of a live measurement in which the polarisation curve is continuously recorded and the polarisation models are applied thereto, as will be explained in more detail later.

As mentioned above, as a further step in the diagnostic method, at least one or all of the extracted diagnostic fuel cell parameter sets can be output. Which of the extracted diagnostic fuel cell parameters are output can if necessary be determined by an optional selection, in particular by discarding individual diagnostic fuel cell parameters, as will be explained in more detail later by way of example.

The diagnostic method may also include the following steps:
specifying fuel cell parameters for the diagnostic fuel cell parameter set to be extracted, and
selecting at least two of the provided polarisation models based on the specified fuel cell parameters in the diagnostic fuel cell parameter set to be extracted,
whereby in particular only the selected polarisation models are applied to the at least one polarisation curve. This ensures that, of the polarisation models provided, only those are selected for application to the polarisation curve that output previously specified fuel cell parameters. Thus, polarisation models that supply diagnostic fuel cell parameter sets that do not provide the specified and thus desired fuel cell parameters are not taken into account. If, for example, an estimate of the degradation of the at least one fuel cell is to be made, the fuel cell parameters required for this can be defined beforehand. Polarisation models that do not supply these in their diagnostic fuel cell parameter sets can then be discarded. This allows an intelligent selection of polarisation models to be made from a variety of polarisation models provided, for example in a database, in order to save computational resources for a corresponding diagnostic system which carries out the diagnostic method, and allows a faster diagnosis.

It can be the case that the diagnostic method further includes comparing the polarisation models provided with available input data and applying those selected polarisation models to which at least one polarisation curve is applied which, in particular, require no further input data other than the available input data. Input data can for example be voltage and/or current at the fuel cells, but also operating conditions such as pressure, temperature, relative humidity, etc. and/or fuel cell data such as Pt loading, membrane thickness, etc. This ensures that only those polarisation models are applied to the at least one polarisation curve which also allow a diagnosis on the basis of the recorded at least one polarisation curve.

Furthermore, it is possible that the goodness of fit of each polarisation model is determined for the at least one polarisation curve, and extracted diagnostic fuel cell parameter sets which fall below a predetermined minimum goodness of fit are discarded. The minimum goodness of fit can be predetermined accordingly to increase the reliability of the diagnostic fuel cell parameter sets. This ensures that only those diagnostic fuel cell parameter sets are supplied for further use, in particular for an output and/or estimation of the degradation of the at least one fuel cell, which are also sufficiently reliable.

Furthermore, it can be the case that the extracted diagnostic fuel cell parameter sets of different polarisation models are compared with each other. This makes it possible to examine the diagnostic fuel cell parameter sets in comparison with each other and to substantiate the diagnostic results insofar as they substantially correspond to each other. This also makes it possible to increase the reliability of the diagnostic method or the results obtained from it.

Most particularly, a common diagnostic fuel cell parameter set can be formed for the at least one fuel cell on the basis of this comparison. In this way, the fuel cell parameters that are considered to be the most reliable in each case can be obtained from the respective diagnostic fuel cell parameter sets and combined into a common diagnostic fuel cell parameter set. However, it is also for example possible to form a common value for the respective fuel cell parameters from the different diagnostic fuel cell parameter sets, for example a mean value, a weighted mean value, a median or similar, whereby these common values then form the common diagnostic fuel cell parameter set.

It is also possible that a plausibility check of the extracted diagnostic fuel cell parameter sets is performed. For example, it can be checked whether the fuel cell parameters of one diagnostic fuel cell parameter set contradict the other diagnostic fuel cell parameter sets or lie outside of predefined value ranges, so that it can be concluded from this that these extracted diagnostic fuel cell parameter sets can be rejected as implausible. This too increases the reliability of the diagnostic method.

It is also possible that fuel cell parameters from extracted fuel cell parameter sets are compared with degradation and/or fault parameters from a database. The database can for example be populated with values from previous diagnostic results and/or values from one or more simulation models. This makes it possible to compare the fuel cell parameters with a database of fault and/or degradation fingerprints in order to estimate a fault, damage to and/or degradation of the at least one fuel cell. In principle, it is also advantageous if the fuel cell parameters are developed in-house, for example via a polarisation curve with a first data set and then, using the same process, via a polarisation curve with a second data set. Consequently, the parameter develops in particular over time.

In particular, it is possible that the degradation of the at least one fuel cell is estimated based on fuel cell parameters of the extracted fuel cell parameter sets. This use of the extracted fuel cell parameter sets is particularly advantageous because several extracted fuel cell parameter sets are available and/or only those that have not been discarded previously are still used. Due to the large amount of parameter information, a very accurate and reliable estimate of the degradation of the at least one fuel cell can be made.

It is also possible that the measurement of the at least one fuel cell is carried out as part of the diagnostic method. In particular, the measurement can be carried out, at least at times, in parallel with the application and/or extraction step of the diagnostic method. In this way, the polarisation curve can be continuously updated on the basis of the measurement and applied in order to provide a live diagnostic method in which the at least one fuel cell can be integrated into a test bench.

It is thereby possible that the measurement of the at least one fuel cell is actively influenced by at least one of the extracted diagnostic fuel cell parameter sets. In other words, a feedback to the measurement method takes place on the basis of at least one of the extracted diagnostic fuel cell parameter sets. By changing measurement parameters in the measurement method, especially on the test bench of the at least one fuel cell, the diagnostic result can be influenced accordingly.

It can also be advantageous if the extracted diagnostic fuel cell parameter sets of the at least one fuel cell are actively influenced by a goodness of fit of each polarisation model. It can therefore be the case that the fuel cell is actively influenced by the extracted diagnostic fuel cell parameter sets.

The subject matter of the present invention also includes a computer program product comprising commands which, when the program is run on a computer, cause this to carry out the diagnostic method according to the invention.

Thus, a computer program product according to the invention brings the same advantages as have been explained in detail with reference to the diagnostic method according to the invention.

The computer program product can be a computer program per se or a product, for example a computer-readable data storage device, on which a computer program can be stored to carry out the method according to the invention. Within the scope of the invention, a computer program product can also advantageously be an analogue circuit board and a screen, for example an oscilloscope.

The subject matter of the present invention also includes a diagnostic system for diagnosing at least one fuel cell of a fuel cell system, wherein the diagnostic system comprises the following modules:
a provision module for providing at least two different polarisation models for extracting a diagnostic parameter set from a polarisation curve of at least one fuel cell,
a recording module for recording at least one polarisation curve from at least one measurement of the at least one fuel cell,
an application module for applying at least two of the previously recorded different polarisation models to the at least one polarisation curve of the at least one fuel cell, and
an extraction module for extracting a diagnostic fuel cell parameter set from the at least one polarisation curve of the at least one fuel cell for each of the applied polarisation models.

Thus, a diagnostic system according to the invention brings the same advantages as have been explained in detail with reference to the diagnostic method according to the invention.

In particular, the diagnostic system can be configured or designed to carry out the diagnostic method according to the invention.

The modules of the diagnostic system can for example in each case be implemented by a separate computer program code or jointly by a common computer program code and/or by separate or common functional units of a computer. It is also possible that individual modules are implemented in a common module. The diagnostic system may in particular comprise one or more computers or be formed by the one or more computers, which may include the individual modules.

The aforementioned modules may also be configured to carry out the other steps of the diagnostic method described herein. However, additional modules can also be provided for each of the individual steps, which modules can be distinguished from each other through corresponding reference to the respective steps.

Further advantages, features and details of the invention are explained in the following description, in which exemplary embodiments are described in detail with reference to the drawings.

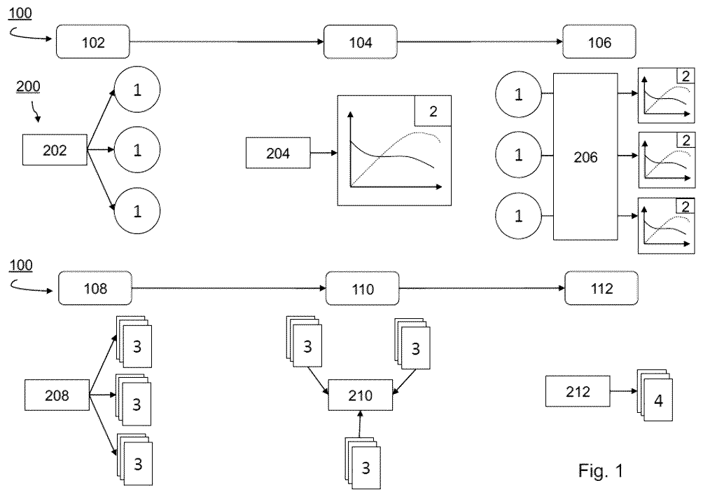

FIG. 1 shows a schematic view of an exemplary embodiment of a diagnostic method 100 and diagnostic system 200 according to the invention.

In a first method step, a provision 102 of the in this case purely exemplary three different polarisation models 1 takes place. These can for example be expressed by one or more mathematical relationships, in particular functions, which differ from each other. The provision 102 is carried out by a provision module 202 of the diagnostic system 200.

In a following method step, a recording 104 of a polarisation curve 2 is carried out based on a measurement (operation) of one or more fuel cells on a corresponding test bench of the fuel cell system of these fuel cells. By way of example, it will be assumed here that this is a fuel cell stack, which may have been measured beforehand or can be measured within the framework of the diagnostic method 100.

The polarisation curve 2 recorded from the measurement indicates different properties of the fuel cell stack. The recording 104 can be carried out by a recording module 204 of the diagnostic system 200.

In a further method step, an application 106 of the different polarisation models 1 to the polarisation curve of the fuel cell stack is carried out by means of an application module 206 of the diagnostic system 200. In a subsequent method step, an extraction 108 of a diagnostic fuel cell parameter set 3 from the polarisation curve 2 of the fuel cell stack is carried out for each of the applied polarisation models 1 by an extraction module 208.

As a result, there are now three extracted diagnostic fuel cell parameter sets 3, each based on different polarisation models 1 which were provided at the beginning.

These diagnostic fuel cell parameter sets 3 can now be output directly by the diagnostic method 100 and the diagnostic system 200, which is not shown, and/or can go through further method steps.

By way of example, FIG. 1 shows how, in a subsequent method step, a comparison 110 of the diagnostic fuel cell parameter sets 3 with each other is carried out by a comparison module 210. Furthermore, FIG. 1 shows, by way of example, how, in a subsequent method step, a formation 112 of a common diagnostic fuel cell parameter set 4 is carried out by a formation module 212 on the basis of the previous comparison. Thus, a common diagnostic fuel cell parameter set 4 is formed for all individual diagnostic fuel cell parameter sets 3 which specifies fuel cell parameters characterising the fuel cell stack that are as accurate as possible. These fuel cell parameters can be output or, in a further method step which is not shown, used to estimate the degradation of the fuel cell stack.

In addition or alternatively, the diagnostic method 100 may comprise further method steps, not shown here, for example a specification of fuel cell parameters which are to be extracted, a comparison with input data, a determination of a goodness of fit, a plausibility check, etc., in particular as described above.

The above explanations of the embodiments describe the present invention exclusively in the context of examples.

### LIST OF REFERENCE SIGNS

100 diagnostic method
102 provision
104 recording
106 application
108 extraction
110 comparison
112 formation
200 diagnostic system
202 provision module
204 recording module
206 application module
208 extraction module
210 comparison module
212 formation module

1. Diagnostic method for diagnosing at least one fuel cell of a fuel cell system, wherein the diagnostic method comprises the following steps:
providing at least two different polarisation models for extracting a diagnostic fuel cell parameter set from a polarisation curve of at least one fuel cell,
recording at least one polarisation curve from at least one measurement of at least one fuel cell,
applying at least two of the previously recorded different polarisation models to the at least one polarisation curve of the at least one fuel cell, and
extracting a diagnostic fuel cell parameter set from the at least one polarisation curve of the at least one fuel cell for each of the applied polarisation models.

2. Diagnostic method according to claim 1, wherein the diagnostic method further comprises the following steps:
specifying fuel cell parameters for the diagnostic fuel cell parameter set to be extracted, and
selecting at least two of the provided polarisation models based on the specified fuel cell parameters in the diagnostic fuel cell parameter set to be extracted,
wherein the selected polarisation models are applied to the at least one polarisation curve.

3. Diagnostic method according to claim 1, wherein the diagnostic method further includes comparing the polarisation models provided with available input data and applying those selected polarisation models to which at least one polarisation curve is applied which require no further input data other than the available input data.

4. Diagnostic method according to claim 1, wherein the goodness of fit of each polarisation model is determined for the at least one polarisation curve and extracted diagnostic fuel cell parameter sets which fall below a predetermined minimum goodness of fit are discarded.

5. Diagnostic method according to claim 1, wherein the extracted diagnostic fuel cell parameter sets of different polarisation models are compared with each other.

6. Diagnostic method according to claim 5, wherein a common diagnostic fuel cell parameter set for the at least one fuel cell is formed on the basis of the comparison.

7. Diagnostic method according to claim 1, wherein a plausibility check of the extracted diagnostic fuel cell parameter sets is performed.

8. Diagnostic method according to claim 1, wherein fuel cell parameters of extracted fuel cell parameter sets are compared with degradation and/or fault parameters from a database.

9. Diagnostic method according to claim 1, wherein the degradation of the at least one fuel cell is estimated on the basis of fuel cell parameters of the extracted fuel cell parameter sets.

10. Diagnostic method according to claim 1, wherein the measurement of the at least one fuel cell is carried out as part of the diagnostic method.

11. Computer program product comprising commands which, when the program is run on a computer, cause this to carry out the diagnostic method according to claim 1.

12. Diagnostic system for diagnosing at least one fuel cell of a fuel cell system, wherein the diagnostic system is wherein the following modules:
a provision module for providing at least two different polarisation models for extracting a diagnostic parameter set from a polarisation curve of a fuel cell,
a recording module for recording at least one polarisation curve from at least one measurement of the at least one fuel cell,
an application module for applying at least two of the previously recorded different polarisation models to the at least one polarisation curve of the at least one fuel cell, and
an extraction module for extracting a diagnostic fuel cell parameter set from the at least one polarisation curve of the at least one fuel cell for each of the applied polarisation models.
